(19) United States
(12) Patent Application Publication
(10) Pub. No.: US 2018/0149918 A1
(43) Pub. Date: May 31, 2018

(54) Specular Display Apparatus and Controlling Method Thereof

(71) Applicants: BOE Technology Group Co., Ltd., Beijing (CN); Beijing BOE Display Technology Co., Ltd., Beijing (CN)

(72) Inventors: Shuai Yuan, Beijing (CN); Xiaona Liu, Beijing (CN); Mengjie Wang, Beijing (CN); Yuqiong Chen, Beijing (CN); Ning Li, Beijing (CN)

(21) Appl. No.: 15/680,696

(22) Filed: Aug. 18, 2017

(30) Foreign Application Priority Data
Nov. 29, 2016 (CN) 201611078519.7

(51) Int. Cl. G02F 1/1335; G02F 1/1343; H01L 51/52; H01L 27/32; C09K 19/38; H01L 51/00

(52) U.S. Cl. CPC G02F 1/133536; G02F 2001/133618; G02F 1/13362; H01L 51/5271; H01L 51/5284; H01L 51/5293; H01L 27/322; C09K 19/38; H01L 51/0034; G02F 2203/07; G02F 2001/133531; G02F 2201/121; G02F 2201/123; G02F 2201/44; G02F 1/13439

(57) ABSTRACT

The present disclosure provides a specular display apparatus and a controlling method. The specular display apparatus includes a display module and a light ray controller. The display module includes a first display panel and a reflection film located at a light exiting side of the first display panel. A reflection surface of the reflection film faces away from the first display panel, and the reflection surface reflects a part of ambient lights which have a polarization direction perpendicular to a direction of a light transmission axis of the reflection film. The light ray controller is provided at a side of the reflection film with the reflection surface and configured to block light rays emitted from the display module and transmit the ambient light reflected by the reflection film, or transmit display light rays emitted from the display module and enable the ambient lights to pass through the reflection film.

### CROSS-REFERENCE TO RELATED APPLICATION

This application claims benefit of the Chinese Patent Application No. 201611078519.7, filed with SIPO on 29 Nov. 2016, entitled with “A Specular Display Apparatus and A Controlling Method Thereof”, which is incorporated herein by reference in entirety.

### BACKGROUND OF THE DISCLOSURE

### Field of the Disclosure

The present disclosure relates to the field of display technology, and in particular, to a specular display apparatus and a controlling method thereof.

### Description of the Related Art

As display technology continuously develops, specular display technique has gradually entered into normal life of people. A specular display apparatus in the prior art can also reflect ambient light during the process of displaying images, so that it can be used as a mirror. However, images reflected and displayed by the specular display apparatus will be superposed so that there are some interferences between the reflected images and the displayed images. In this way, the user clearly watches neither the reflected images nor the displayed images, thereby reducing the display and reflection effect of the specular display apparatus.

### SUMMARY

Embodiments of the present disclosure provide a specular display apparatus and a controlling method thereof.

In one aspect, it provides a specular display apparatus, comprising:

a display module comprising:
a first display panel, and
a reflection film located at a light exiting side of the first display panel, wherein a reflection surface of the reflection film faces away from the first display panel, and the reflection surface reflects a part of ambient lights which have a polarization direction perpendicular to a direction of a light transmission axis of the reflection film;

a light ray controller, provided at a side of the reflection film where the reflection surface is located and configured to:
block light rays emitted from the display module and transmit the ambient light reflected by the reflection film, or
transmit display light rays emitted from the display module and enable the ambient lights to pass through the reflection film.

In one example, the light ray controller comprises:

a first liquid crystal display panel, and

a first polarizer, located at a light exiting side of the first liquid crystal display panel;

wherein the first polarizer has a light transmission axis identical with the light transmission axis of the reflection film.

In one example, the display module further comprises a second polarizer located at a light incident side of the first display panel, wherein the second polarizer has a light transmission axis perpendicular to the light transmission axis of the reflection film.

In one example, the first display panel is a second liquid crystal display panel.

In one example, a common electrode and a pixel electrode of the second liquid crystal display panel are located on an array substrate of the second liquid crystal display panel.

In one example, the pixel electrode and the common electrode of the second liquid crystal display panel are disposed in different layers respectively.

In one example, the pixel electrode and the common electrode are respectively a strip-shaped electrode and a planar electrode; or

the pixel electrode and the common electrode are respectively a planar electrode and a strip-shaped electrode; or

both the pixel electrode and the common electrode are strip-shaped electrodes.

In one example, the pixel electrode and the common electrode of the second liquid crystal display panel both are strip-shaped electrodes, and are crossed with each other in a same layer.

In one example, the reflection film is a reflective polarizer.

In one example, the reflection film is an advanced polarizer film.

In one example, the display module further comprises a light source at a side of the second polarizer facing away from the first display panel.

In one example, the first display panel is an organic electroluminescent display panel.

In one example, the organic electroluminescent display panel is configured to emit linearly polarized lights, a polarization direction of which is identical with the light transmission axis of the reflection film.

In one example, a light emitting layer of the organic electroluminescent display panel comprises fluorine-based polymer liquid crystal materials.

In one example, the organic electroluminescent display panel further comprises a color filter layer at a light exiting side of the light emitting layer.

In one example, the first display panel is an organic electroluminescent display panel.

In one example, the first display panel is an organic electroluminescent display panel.

In another aspect, it provides a method of controlling the specular display apparatus as described above, comprising:

receiving a first control signal by means of the light ray controller, and under a control of the first control signal, transmitting ambient light rays reflected by the reflection film and blocking light rays emitted from the display module by means of the light ray controller; or

receiving a turn-on signal by means of the display module and performing a display, receiving a second control signal by means of the light ray controller, and under a control of the second control signal, transmitting display light rays emitted from the display module and enabling the ambient light rays to pass through the reflection film by means of the light ray controller;

wherein the first control signal is different from the second control signal.

In one example, the light ray controller comprises a first liquid crystal display panel and a first polarizer, and the display module comprises a second liquid crystal display panel, a second polarizer and a light source,

the step of under the control of the first control signal, transmitting ambient light rays reflected by the reflection film and blocking light rays emitted from the display module by means of the light ray controller comprises:

receiving the first control signal by means of the first liquid crystal display panel and applying a signal of no voltage to a pixel electrode and a common electrode of the first liquid crystal display panel respectively.

In one example, the light ray controller comprises a first liquid crystal display panel and a first polarizer, and the display module comprises a second liquid crystal display panel, a second polarizer and a light source, the step of receiving the turn-on signal by means of the display module and performing the display comprises:

receiving the turn-on signal for the light source to emit light;

receiving the turn-on signal for the second liquid crystal display panel and applying a voltage to a pixel electrode and a common electrode of the second liquid crystal display panel respectively; and

the step of under the control of the second control signal, transmitting display light rays emitted from the display module by means of the light ray controller comprises:

receiving the second control signal by the first liquid crystal display panel, and applying a voltage signal to a pixel electrode and a common electrode of the first liquid crystal display panel respectively.

### BRIEF DESCRIPTION OF THE DRAWINGS

In order to clearly describe technique schemes in embodiments of the present disclosure or in the prior art, accompanying drawings used for illustrating these embodiments will be simply described below. Obviously, the accompanying drawings described below merely refer to some of embodiments of the present disclosure, and those ordinary skilled in the art may arrive at other accompanying drawings based on these accompanying drawings without any creative efforts.

FIG. 1a is a schematic view of principles that a specular display apparatus achieves a specular effect in accordance with an embodiment of the present disclosure;

FIG. 1b is a schematic view of principles that a specular display apparatus achieves a display effect in accordance with an embodiment of the present disclosure;

FIG. 2 is a schematic view of a light ray controller as shown in FIG. 1a or 1b;

FIG. 3a is a schematic view of a propagation path of ambient light rays in a state that the light ray controller shown in FIG. 2 is turned off;

FIG. 3b is a schematic view of a propagation path of ambient light rays in a state that the light ray controller shown in FIG. 2 is turned on;

FIG. 4 is a schematic view of structural details of a display module as shown in FIG. 1a or 1b;

FIG. 5 is a schematic view showing one arrangement that a common electrode and pixel electrodes are provided on a second liquid crystal display panel, when a first display panel in FIG. 4 is the second liquid crystal display panel;

FIG. 6 is a schematic view showing another arrangement that a common electrode and pixel electrodes are provided on a second liquid crystal display panel, when a first display panel in FIG. 4 is the second liquid crystal display panel;

FIG. 7a is a schematic view showing propagation paths of display light rays and ambient light rays when the specular display apparatus in accordance with an embodiment of the present disclosure achieves the display function;

FIG. 7b is a schematic view showing propagation paths of display light rays and ambient light rays when the specular display apparatus in accordance with an embodiment of the present disclosure achieves the specular function;

FIG. 8 is a schematic view showing detailed structure of another display module as shown in FIG. 1a or 1b;

FIG. 9 is a flowchart of a controlling method of a specular display apparatus in accordance with an embodiment of the present disclosure; and

FIG. 10 is a flowchart of a controlling method of another specular display apparatus in accordance with an embodiment of the present disclosure.

### DETAILED DESCRIPTION OF PREFERRED EMBODIMENTS OF THE DISCLOSURE

Below, technical solutions in embodiments of the present disclosure will be described clearly and completely in combination with the accompanying drawings therein. Obviously, the described embodiments are only a part of embodiments of the present disclosure, rather than all of the embodiments. On the basis of the embodiments in the present disclosure, the ordinarily skilled person in the art can arrive at other embodiments without any creative efforts, which shall fall into the scope of the present disclosure.

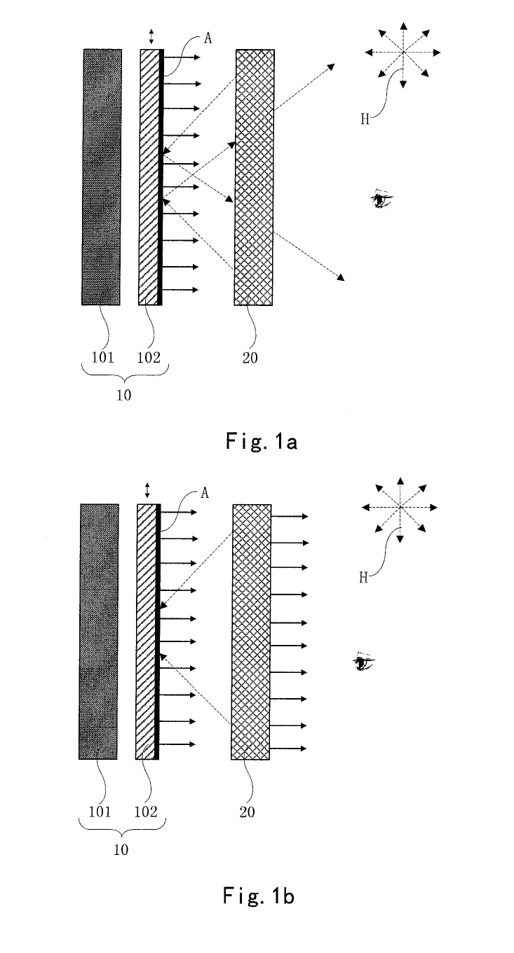

An embodiment of the present disclosure provides a specular display apparatus. As shown in FIG. 1a or 1b, it includes a display module 10, which includes a first display panel 101 and a reflection film 102 at a light exiting side of the first display panel 101.

The reflection film 102 has a reflection surface A facing away from the first display panel 101. The reflection surface A is used to reflect a part of ambient lights which have a polarization direction perpendicular to a direction where a light transmission axis of the reflection film 102 extends.

In addition, the specular display apparatus further includes a light ray controller 20 located at a side of the reflection film 102 where the reflection surface A is located. As shown in FIG. 1a, the light ray controller 20 is used to block light rays (as shown by solid arrows in FIG. 1a) emitted from the display module 10, and transmit the ambient lights (as shown by dashed arrows in FIG. 1a, and emitted by a light source H of the ambient light) reflected by the reflection surface A of the reflection film 102. Alternatively, the light ray controller 20 as shown in FIG. 1b is used to transmit the display light rays emitted from the display module 10 and transmit the ambient light rays through the reflection film 102. The ambient light source H can be a light source except the specular display apparatus, for example sunlight or light from a lamp and the like.

Concerning the above, when the specular display apparatus achieves the specular function, the light ray controller 20 can block the light rays emitted from the display module 10, and transmit the ambient light reflected by the reflection surface A of the reflection film 102. Alternatively, when the specular display apparatus achieves displaying pictures, the light ray controller transmits the display light rays emitted from the display module 10 and transmits ambient lights through the reflection film. In this way, the light ray controller 20 can make the light rays reflected by the reflection film 102 and the display light rays of the display module 10 not overlap with each other, so that it can prevent the problem that the reflected images of the specular display apparatus and the displayed images disturb with each other.

In the following specific embodiments, the detailed structures of the display module 10 and the light ray controller 20 will be illustrated completely.

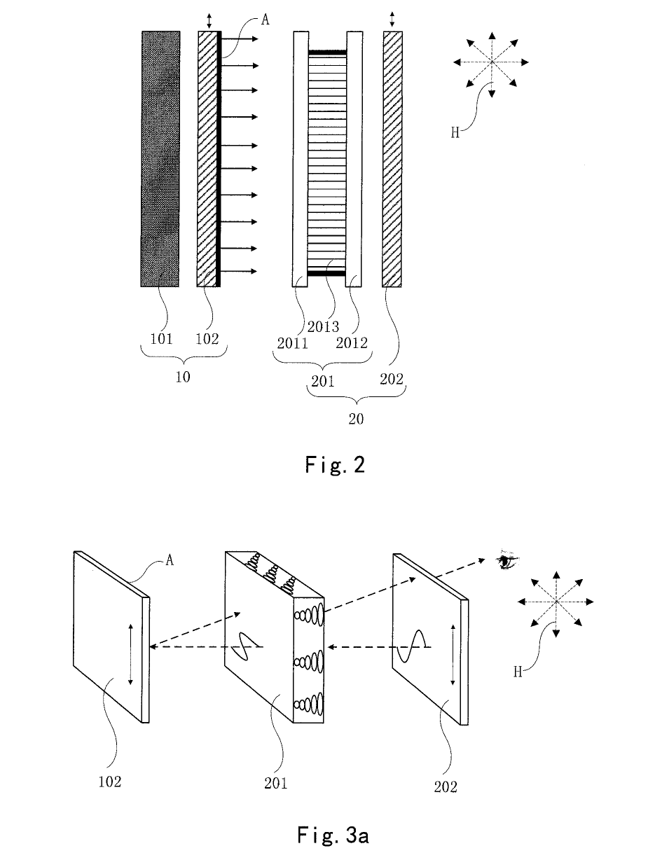

In one example, as shown in FIG. 2, the light ray controller 20 includes a first liquid crystal display panel 201 and a first polarizer 202 at a light exiting side of the first liquid crystal display panel 201.

The first liquid crystal display panel 201 includes an array substrate 2011 and an opposite substrate 2012 arranged opposite to each other and assembled together, and a liquid crystal layer 2013 between them. In addition, a common electrode of the first liquid crystal display panel 201 is located on the opposite substrate 2012, while pixel electrodes of the first liquid crystal display panel 201 are located on the array substrate 2011.

In this case, the first liquid crystal display panel 201 is a TN (Twist Nematic) liquid crystal display panel. Specifically, the TN liquid crystal display panel employs a vertical electric field principle. A vertical electric field is formed between the common electrode on the opposite substrate 2012 and the pixel electrodes on the array substrate 2011 which are arranged opposite to each other, so as to drive the liquid crystal molecules with TN mode.

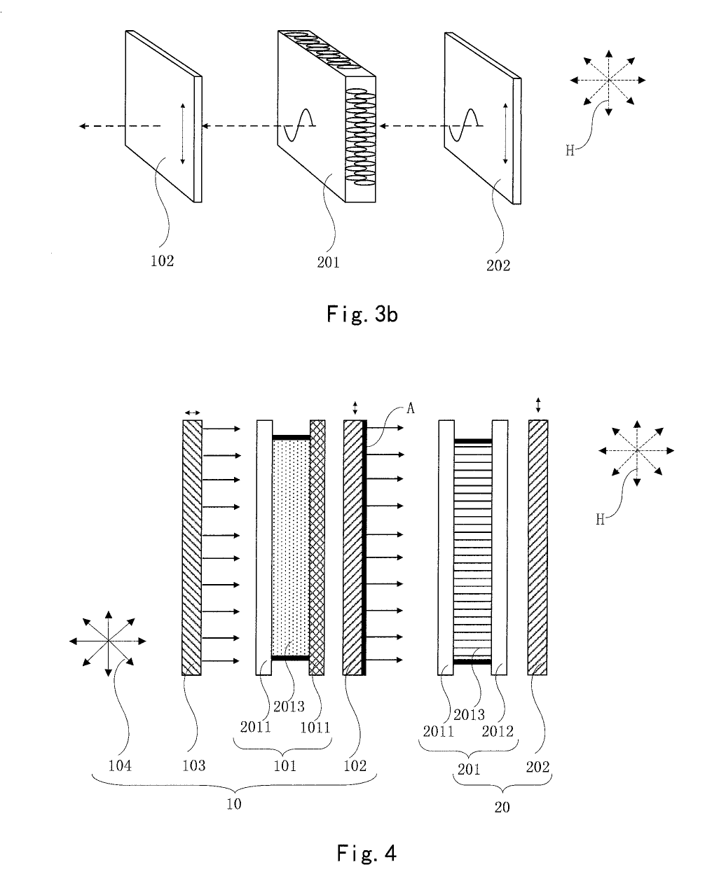

On a basis of this, the first polarizer 202 has a same light transmission axis as that of the reflection film 102. In this way, when no voltage is applied between the common electrode and the pixel electrodes of the first liquid crystal display panel 201, the liquid crystal molecules in the liquid crystal layer 2013 will twist. In this case, as shown in FIG. 3a, the first polarizer 202 permits the ambient lights having the same direction as the light transmission axis thereof to transmit, and through optical rotation effect of the liquid crystal layer 2013, the polarization direction thereof will change. Since the reflection film 102 and the first polarizer 202 have the same light transmission axis, the ambient lights which have passed through the liquid crystal layer 2013 cannot transmit through the reflection film 102, and be reflected by the reflection surface A of the reflection film 102. At this time, after the reflected lights are affected by the optical rotation effect of the liquid crystal layer 2013 at second time, they have the same polarization direction as the direction of the light transmission axis of the first polarizer 202, so that the reflected lights passed through the liquid crystal layer 2013 can be transmitted through the first polarizer 202. Thus, the specular display apparatus can achieve the specular function.

With such arrangement, if the display module displays the pictures, due to the polarization analyzer effect of the reflection film 102, the display light rays which have the polarization direction identical to the direction of the light transmission axis of the reflection film 102, can pass through it. Continuously, due to the optical rotation effect of the liquid crystal layer 2013, the display light rays that have passed through the liquid crystal layer 2013 have the polarization direction perpendicular to the direction of the light transmission axis of the first polarizer 202. Thus, the display light rays having passed through the liquid crystal layer 2013 cannot pass through the first polarizer 202. At this time, when no voltage is applied between the common electrode and the pixel electrodes of the first liquid crystal display panel 201, the light ray controller 20 still can block the display light rays, even though the display module has emitted the display light rays. In this way, when achieving the specular function, the specular display apparatus can prevent the display light rays from disturbing the reflection light rays of the ambient lights.

Alternatively, when a voltage is applied between the common electrode and the pixel electrode of the first liquid crystal display panel 201, the liquid crystal molecules in the liquid crystal layer 2013 do not twist. In this case, as shown in FIG. 3b, the first polarizer 202 permits the ambient light having a polarization direction identical to the direction of its light transmission axis to pass through, and after passing through the liquid crystal layer 2013, the polarization direction thereof does not change. Since the light transmission axis of the reflection film 102 is identical with that of the first polarizer 202, the ambient light passes through the reflection film 102, so that they would not be reflected by the reflection surface A of the reflection film 102. Meanwhile, when the display module is displaying, through the polarization analyzer effect of the reflection film 102, the display light rays having the polarization direction identical with the direction of the light transmission axis of the reflection film 102 can pass through the reflection film 102. On a basis of this, the display light rays pass through the liquid crystal layer 2013 and the polarization directions thereof do not change. Because the light transmission axis of the reflection film 102 is identical with that of the first polarizer 202, the above display light rays having passed through the liquid crystal layer 2013 in turn can pass through the first polarizer 202. In this way, such specular display apparatus can achieve the display function. In addition, because the ambient lights pass through the reflection film 102, they would not be reflected by the reflection surface A of the reflection film 102. Therefore, when the specular display apparatus is displaying pictures, it can prevent the reflection light rays from the ambient lights from disturbing the display light rays.

It should be noted that the present disclosure does not make any limitation to alignment materials of the liquid alignment layers on the first liquid crystal display panel 201, for example the parallel alignment materials can be used as the material of the above described liquid alignment layers. It is manufactured by the parallel friction process so that the light transmission axis of the first polarizer 202 lies at an angle of 45° with respect to the friction direction in the friction process. In this way, the first liquid crystal display panel 201 is used to compose a PCP (Pi(π) Cell Panel) display apparatus.

On this basis, the display module 10 as shown in FIG. 4 further includes a second polarizer 103 at a light incidence side of the first display panel 101. The light transmission axis of the second polarizer 103 is perpendicular to that of the reflection film 102. It shall be noted that the first display panel 101 in the present disclosure does not include a polarizer.

On this basis, the first display panel 101 is a second liquid crystal display panel, which includes an array substrate 2011 and a color filter substrate 1011 arranged opposite to each other and assembled together. The common electrode of the second liquid crystal display panel is located on the array substrate 2011. In this case, the common electrode and the pixel electrodes of the second liquid crystal display panel both are located on the array substrate 2011.

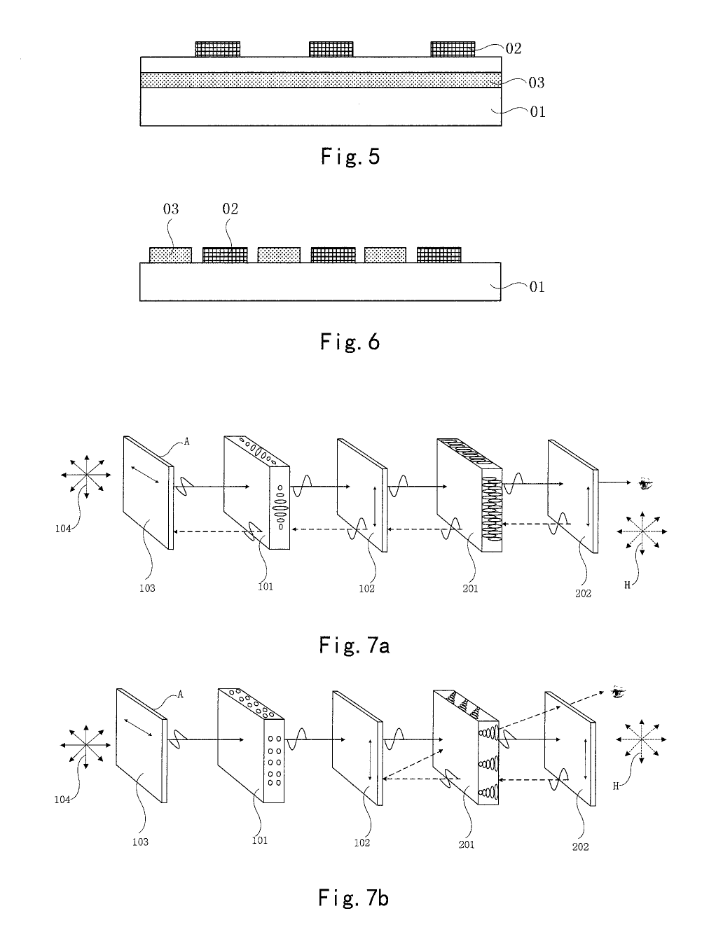

On this basis, the setting of the common electrode and the pixel electrodes is specified as for example as shown in FIG. 5, the pixel electrodes 02 and the common electrode 03 are located in different layers on the base substrate 01 of the array substrate 2011. For example, the pixel electrodes 02 are strip-shaped electrodes and the common electrode 03 is a planar electrode. Alternatively, the common electrode 03 is in a form of strip-shaped electrodes and pixel electrodes 02 are a planar electrode; or otherwise, the common electrode 03 and the pixel electrodes 02 both are strip-shaped electrodes. The present disclosure does not make any limitation to them. In addition, the present disclosure does not make any limitation to the relative position relationship of the pixel electrodes 02 and the common electrode 03. An explanation is made taking the case of FIG. 5 as an example in which the pixel electrodes 02 are located at the upper position and the common electrode 03 is located at the lower position.

Or, for example, as shown in FIG. 6, the pixel electrodes 02 and the common electrode 03 of the second liquid crystal display panel both are in a form of strip-shaped electrodes, and are crossed with each other in a same layer.

In addition, the display module 10 further includes a light source 104 located at one side of the second polarizer 103 facing away from the first display panel 101. Please be noted that when the second liquid crystal display panel is displaying the images, the voltage is applied onto the common electrode 03 and the pixel electrodes 02 of the second liquid crystal display panel. At this time, as shown in FIG. 7a, a part of the light rays emitted from the light source 104 which possesses the polarization direction identical with the direction of the light transmission axis of the second polarizer 103 can pass through the second polarizer 103, and due to the optical rotation effect of the liquid crystal layer 2013 of the second liquid crystal display panel, the polarization direction of outgoing light rays that have passed through the liquid crystal layer 2013 changes and become identical with the direction of the light transmission axis of the reflection film 102, so that the light rays that have passed through the first display panel 102 can transmit through the reflection film 102.

The above light source 104 can be a LED (Light Emitting-Diode) light bar. Furthermore, the light source 104 can provide the backlight source to the second liquid crystal display panel in an edge lighting mode or direct back lighting mode. The present disclosure does not make any limitation to this.

In this case, it can be known from the above description that when the light ray controller 20 turns on (i.e., when a voltage is applied onto the common electrode and the pixel electrodes of the first liquid crystal display panel 201 in the light ray controller 20), the liquid crystal molecules in the liquid crystal layer 2013 of the first liquid crystal display panel 201 do not twist. At this time, the display light rays (as shown by the solid arrows) which outgo from the second liquid crystal display panel (i.e., the above first display panel 101) can pass through the light ray controller 20, so that the user can watch the display picture. In addition, among the ambient lights emitted from the ambient light source H which are incident on the light ray controller 20, a part thereof having the polarization direction identical with the direction of the light transmission axis of the first polarizer 202 in the light ray controller 20 can successively pass through the light ray controller 20 and the reflection film 102 and due to the optical rotation effect of the liquid crystal layer 2013 of the second liquid crystal display panel, the polarization direction of the above ambient lights that have passed through the liquid crystal layer 2013 becomes identical with the direction of the light transmission axis of the second polarizer 103, so that they can be absorbed by the second polarizer 103. Therefore, it can prevent the specular display apparatus from reflecting the ambient lights. In this way, when the specular display apparatus is displaying the images, it can prevent the reflection light rays of the ambient lights from disturbing the display light rays.

In addition, it can be seen from the above description that when the light ray controller 20 is turned off (i.e., no voltage is applied between the common electrode and the pixel electrodes of the first liquid crystal display panel 201 of the light ray controller 20), as shown in FIG. 7b, the display light rays which have passed through the reflection film 102 and then passed through the first liquid crystal display panel 201, due to the optical rotation effect of the first liquid crystal display panel 201, have the polarization direction perpendicular to the direction of the light transmission axis of the first polarizer 202, so that the display light rays cannot pass through the first polarizer 202. In this case, the user cannot watch the displayed image. However, among the ambient lights emitted from the ambient light source H, a part thereof has the polarization direction identical to the direction of the light transmission axis of the first polarizer 202, and after it passes through the first liquid crystal display panel 201, due to the optical rotation effect of the first liquid crystal display panel 201, its polarization direction becomes perpendicular to the direction of the light transmission axis of the reflection film 201, so that they are reflected by the reflection film. And then, due to the optical rotation effect of the first liquid crystal display panel 201, the polarization direction of the reflected ambient lights that have passed through the first liquid crystal display panel 201 at second times has become identical with the direction of the light transmission axis of the first polarizer 202. In this way, they can pass through the first polarizer 202 and the specular function is achieved herein. Therefore, when the specular display apparatus achieves the specular function, it can prevent the display light rays from disturbing the reflection light rays of the ambient lights.

Concerning the above, the reflection film 102 can permit the light rays having the polarization direction identical to the direction of its light transmission axis to pass through, and reflect the light rays having the polarization direction perpendicular to the direction of its light transmission axis. Therefore, in one example, the above reflection film 102 can be an Advanced Polarizer Film (abbreviated as APF).

In addition, in order to follow a narrow-frame design trend of the above specular display apparatus, in one example, the second liquid crystal display panel can be chosen as a Super Narrow Bezel (abbreviated as SNB) liquid crystal display panel.

It should be noted that the present disclosure does not limit the size of the specular display apparatus, for example, when the first liquid crystal display panel 201 of the light ray controller 20 and the second liquid crystal display panel (i.e., the first display panel 102) both have a size of 55 inches, the specular display apparatus also has a size or specification of 55 inches.

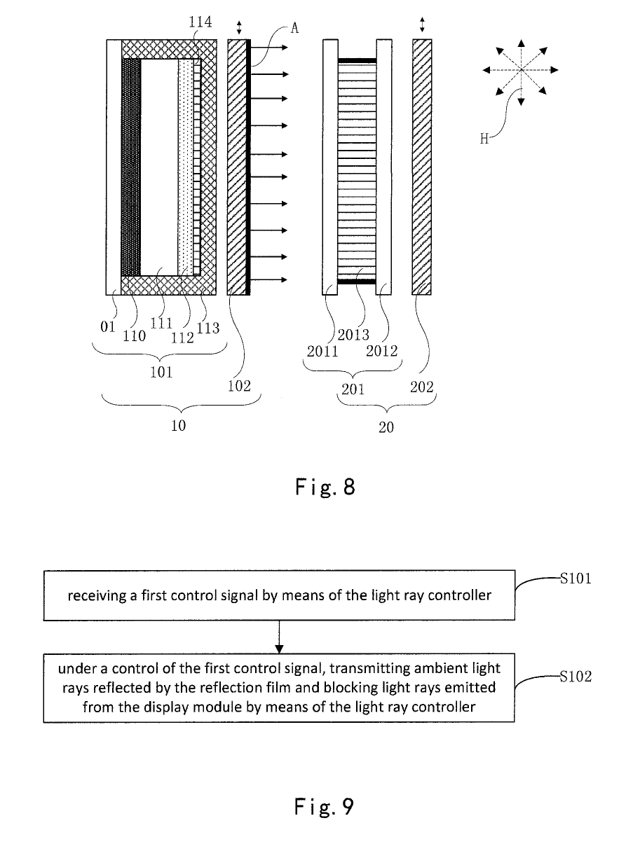

In another example, the structural differences of the light ray controller 20 from the above light ray controllers lie in that the first display panel 101 is an organic electroluminescent display panel. This organic electroluminescent display panel as shown in FIG. 8 includes an anode 110, an organic light emitting function layer 111, a cathode 112 in sequence manufactured on a base substrate 01, and further includes a packaging cover 113. Specifically, the organic light emitting function layer 111 includes an electron hole injection layer, an electron hole transmission layer, a light emitting layer, an electron transmission layer and an electron injection layer or the like. In this case, when the light ray controller 20 turns on, the display light rays emitted from the first display panel 101 can be transmitted through the light ray controller 20, so as to achieve the display function. At this time, the ambient lights which have transmitted through the light ray controller 20 and are incident on the reflection film 102, have the polarization direction identical to the light transmission axis of the reflection film 102, so that they pass through the reflection film 102. In addition, when the light ray controller 20 turns off, the display light rays emitted from the first display panel 101 are blocked by the light ray controller 20 and cannot pass through it. At this time, the reflection light rays of the ambient lights can pass through the light ray controller 20, so as to achieve the specular function. Because the propagation process of the optical path of the display light rays and the ambient light rays are the same as those described with respect to the liquid crystal display panel, they are not discussed herein.

Further, the above organic electroluminescent display panel can also emit the linearly polarized lights. In this case, the material for forming the light emitting layer of the organic electroluminescent display panel includes fluorine-based polymer liquid crystal materials. The fluorine-based polymer liquid crystal materials are processed for alignment, so that the light emitting layer can emit the white polarized light, the polarization direction of which is identical to the light transmission axis of the reflection film 103. In addition, in order to achieve the color display, the organic electroluminescent display panel further includes a filtering layer 114 located at the light exiting side of the light emitting layer.

In this way, since the light emitting layer itself can emit the polarized light which is identical to the direction of the light transmission axis of the reflection film 102, so that the light rays emitted from the light emitting layer can fully pass through the reflection film 102, thereby avoiding the light ray loss during the polarization analyzing process of the reflection film 102 to the light rays emitted from the organic electroluminescent display panel, and improving the utilization of the light rays.

An embodiment of the present disclosure provides a method for controlling any of the above described specular display apparatus. As shown in FIG. 9, the method includes:

Step S101, receiving a first control signal by means of the light ray controller 20.

Step S102, transmitting light rays (as shown by the dashed arrows) reflected by the reflection film 102 and blocking the light rays (as shown by the solid arrows) emitted from the display module 101, under a control of the first control signal, for example by means of the light ray controller 20 as shown in FIG. 1a. At this time, no matter whether the display module 10 emits the display light rays or not, the specular display apparatus can achieve the specular function and the user cannot watch the displayed pictures.

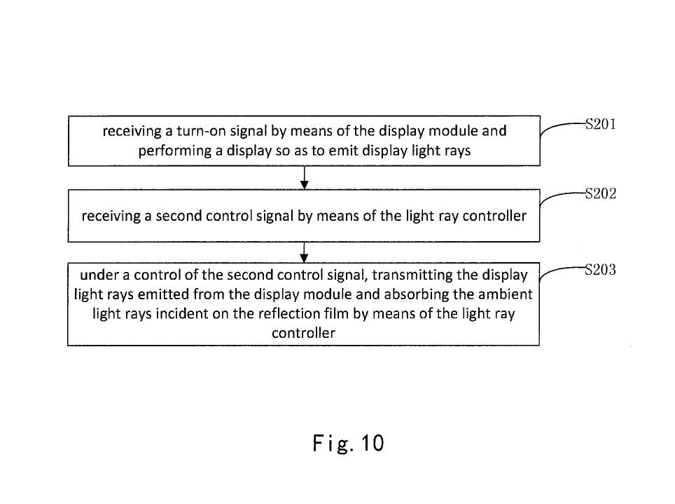

Or, the above controlling method as shown in FIG. 10 includes:

Step S201, receiving a turn-on signal by means of the display module 10 and displaying to emit the display light rays.

Step S202, receiving a second control signal by means of the light ray controller 20.

Step S203, transmitting display light rays (as shown by the solid arrows) emitted from the display module 10 and absorbing the ambient lights (as shown by the dashed arrows) incident on the reflection film 102, under a control of the second control signal, for example by means of the light ray controller 20 as shown in FIG. 1b. At this time, the specular display apparatus can achieve the display function and the user cannot watch the mirror effect.

Specifically, the first control signal is different from the second control signal.

Concerning the above, when the specular display apparatus achieves the specular function, the light ray controller 20 can block the light rays emitted from the display module 10 and transmit the ambient lights reflected by the reflection surface A of the reflection film 102. Alternatively, when the specular display apparatus is displaying the display pictures, the light ray controller 20 is configured to transmit the display light rays emitted from the display module 10 and to make the ambient lights pass through the reflection film 102. In this way, the light ray controller 20 can enable the light rays reflected by the reflection film 102 and the display light rays of the display module 10 not to overlap with each other, thereby it can prevent the problem that there are some disturbance between the reflection images and the display images of the specular display apparatus.

Below, a method of controlling the specular display apparatus to achieve the specular function is described in detail.

Specifically, as shown in FIG. 4, when the light ray controller 20 includes a first liquid crystal display panel 201 and a first polarizer 202, and the display module 10 includes a second liquid crystal display panel 102, a second polarizer 103 and a light source 104, the step S102 includes:

receiving the first control signal by means of the first liquid crystal display panel 201 and applying a signal of no voltage to the pixel electrodes and the common electrode of the first liquid crystal display panel 201 respectively.

Specifically, the first liquid crystal display panel 201 is a TN liquid crystal display panel, and thus when no voltage signal is applied to the pixel electrodes and the common electrode, the liquid crystal molecules in the liquid crystal layer 2013 will twist. In this case, as shown in FIG. 3a, the first polarizer 202 permits the ambient lights identical to its light transmission axis to pass through, and due to the optical rotation effect of the liquid crystal layer 2013, the polarization direction of the ambient lights that have passed through the liquid crystal layer 2013 will change. Because the ambient lights cannot pass through the reflection film 102 but are reflected by the reflection surface A of the reflection film 102, at this time of passing through the liquid crystal layer 2013 again, due to the optical rotation effect, the polarization direction of the reflection light rays is identical to the direction of the light transmission axis of the first polarizer 202, so that the reflection light rays can pass through the first polarizer 202. Therefore, the specular display apparatus can achieve the specular function.

On this basis, if the display module displays the pictures, due to the polarization analyzing effect of the reflection film 102, the display light rays which have the polarization direction identical to the direction of the light transmission axis of the reflection film 102, can pass through. Continually, due to the optical rotation effect of the liquid crystal layer 2013, the polarization direction of the display light rays that have passed through the liquid crystal layer 2013 becomes perpendicular to the direction of the light transmission axis of the first polarizer 202, and thus the display light rays cannot pass through the first polarizer 202. Therefore, when no voltage is applied to the common electrode and the pixel electrode of the first liquid crystal display panel 201, even though the display panel emits the display light rays, the light ray controller 20 can still block the outgoing of the display light rays. Thus, when the specular display apparatus achieves the specular function, it can prevent the display light rays from disturbing the reflection light rays of the ambient lights.

Below, a method of controlling the specular display apparatus to achieve the display function is described in detail.

Specifically, as shown in FIG. 4, in a case that the light ray controller 20 includes a first liquid crystal display panel 201 and a first polarizer 202, and the display panel 10 includes a second liquid crystal display panel 101, a second polarizer 103 and a light source 104, the step S201 includes:

Firstly, receiving the turn-on signal for the light source 104 to emit light;

Secondly, receiving the above turn-on signal for the second liquid crystal display panel 101 and applying the voltage to the pixel electrodes and the common electrode of the second liquid crystal display panel 101.

In this case, the second liquid crystal display panel 101 is displaying the pictures. Specifically, as shown in FIG. 7a, a part of the light rays emitted from the light source 104 which have the polarization direction identical to the direction of the light transmission axis of the second polarizer 103 can pass through the second polarizer 103, and through the optical rotation effect of the liquid crystal layer 2013 of the second liquid crystal display panel, the polarization direction of the outgoing light rays will change and become identical to the direction of the light transmission axis of the reflection film 102, so that the light rays can pass through the reflection film 102.

In addition, the above step S203 includes: receiving the second control signal for the first liquid crystal display panel 201 and applying the voltage to the pixel electrodes and the common electrode of the first liquid crystal display panel 201.

In this case, the liquid crystal molecules in the liquid crystal layer 2013 of the first liquid crystal display panel 201 do not twist. The display light rays (as shown by the solid arrows) emitted from the second liquid crystal display panel (i.e., the first display panel 101) can pass through the light ray controller 20, so that the user can watch the display picture. In addition, a part of the ambient lights incident on the light ray controller 20 and emitted from the ambient light source H which have the polarization direction identical to the direction of the light transmission axis of the first polarizer 202, can in sequence pass through the light ray controller 20 and the reflection film 20, and through the optical rotation effect of the liquid crystal layer 2013 of the second liquid crystal display panel, the polarization direction of the ambient lights that have passed through the liquid crystal layer 2013 becomes identical to the second polarizer 103 and they are absorbed by the second polarizer 103. It can prevent the reflection of the specular display apparatus to the ambient lights. In this way, when the specular display apparatus is displaying the images, it can prevent the reflection light rays of the ambient lights from disturbing the display light rays.

The above described embodiments are only some specific embodiments of the present disclosure. However, the scope of the present disclosure is not limited to this. All of modifications, alternatives and improvements made without departing from the principles and spirit of the disclosure should fall within the protection scope of the present disclosure. Therefore, the scope of the present disclosure shall be defined by the appended claims.

What is claimed is:

1. A specular display apparatus, comprising:
a display module comprising:
a first display panel, and
a reflection film located at a light exiting side of the first display panel, wherein a reflection surface of the reflection film faces away from the first display panel, and the reflection surface reflects a part of ambient lights which have a polarization direction perpendicular to a direction of a light transmission axis of the reflection film;
a light ray controller, provided at a side of the reflection film where the reflection surface is located and configured to:
block light rays emitted from the display module and transmit the ambient light reflected by the reflection film, or
transmit display light rays emitted from the display module and enable the ambient lights to pass through the reflection film.

2. The specular display apparatus according to claim 1, wherein the light ray controller comprises:
a first liquid crystal display panel, and
a first polarizer, located at a light exiting side of the first liquid crystal display panel;
wherein the first polarizer has a light transmission axis identical with the light transmission axis of the reflection film.

3. The specular display apparatus according to claim 2, wherein the display module further comprises a second polarizer located at a light incident side of the first display panel, wherein the second polarizer has a light transmission axis perpendicular to the light transmission axis of the reflection film.

4. The specular display apparatus according to claim 3, wherein the first display panel is a second liquid crystal display panel.

5. The specular display apparatus according to claim 4, wherein a common electrode and a pixel electrode of the second liquid crystal display panel are located on an array substrate of the second liquid crystal display panel.

6. The specular display apparatus according to claim 5, wherein the pixel electrode and the common electrode of the second liquid crystal display panel are disposed in different layers respectively.

7. The specular display apparatus according to claim 6, wherein
the pixel electrode and the common electrode are respectively a strip-shaped electrode and a planar electrode; or
the pixel electrode and the common electrode are respectively a planar electrode and a strip-shaped electrode; or
both the pixel electrode and the common electrode are strip-shaped electrodes.

8. The specular display apparatus according to claim 5, wherein the pixel electrode and the common electrode of the second liquid crystal display panel both are strip-shaped electrodes, and are crossed with each other in a same layer.

9. The specular display apparatus according to claim 1, wherein the reflection film is a reflective polarizer.

10. The specular display apparatus according to claim 3, wherein the reflection film is an advanced polarizer film.

11. The specular display apparatus according to claim 3, wherein the display module further comprises a light source at a side of the second polarizer facing away from the first display panel.

12. The specular display apparatus according to claim 1, wherein the first display panel is an organic electroluminescent display panel.

13. The specular display apparatus according to claim 12, wherein the organic electroluminescent display panel is configured to emit linearly polarized lights, a polarization direction of which is identical with the light transmission axis of the reflection film.

14. The specular display apparatus according to claim 13, wherein a light emitting layer of the organic electroluminescent display panel comprises fluorine-based polymer liquid crystal materials.

15. The specular display apparatus according to claim 13, wherein the organic electroluminescent display panel further comprises a color filter layer at a light exiting side of the light emitting layer.

16. The specular display apparatus according to claim 2, wherein the first display panel is an organic electroluminescent display panel.

17. The specular display apparatus according to claim 3, wherein the first display panel is an organic electroluminescent display panel.

18. A method of controlling the specular display apparatus according to claim 1, comprising:
receiving a first control signal by means of the light ray controller, and under a control of the first control signal, transmitting ambient light rays reflected by the reflection film and blocking light rays emitted from the display module by means of the light ray controller; or
receiving a turn-on signal by means of the display module and performing a display, receiving a second control signal by means of the light ray controller, and under a control of the second control signal, transmitting display light rays emitted from the display module and enabling the ambient light rays to pass through the reflection film by means of the light ray controller;
wherein the first control signal is different from the second control signal.

19. The method according to claim 18, wherein the light ray controller comprises a first liquid crystal display panel and a first polarizer, and the display module comprises a second liquid crystal display panel, a second polarizer and a light source,
the step of under the control of the first control signal, transmitting ambient light rays reflected by the reflection film and blocking light rays emitted from the display module by means of the light ray controller comprises:
receiving the first control signal by means of the first liquid crystal display panel and applying a signal of no voltage to a pixel electrode and a common electrode of the first liquid crystal display panel respectively.

20. The method according to claim 18, wherein the light ray controller comprises a first liquid crystal display panel and a first polarizer, and the display module comprises a second liquid crystal display panel, a second polarizer and a light source, the step of receiving the turn-on signal by means of the display module and performing the display comprises:
receiving the turn-on signal for the light source to emit light;
receiving the turn-on signal for the second liquid crystal display panel and applying a voltage to a pixel electrode and a common electrode of the second liquid crystal display panel respectively; and
the step of under the control of the second control signal, transmitting display light rays emitted from the display module by means of the light ray controller comprises:
receiving the second control signal by the first liquid crystal display panel, and applying a voltage signal to a pixel electrode and a common electrode of the first liquid crystal display panel respectively.
